(19) United States
(12) Patent Application Publication
(10) Pub. No.: US 2024/0412999 A1
(43) Pub. Date: Dec. 12, 2024

(54) CERAMIC SUSCEPTOR AND METHOD OF MANUFACTURING THE SAME

(71) Applicant: MiCo Ceramics Ltd., Anseong-si (KR)

(72) Inventors: Junghyun PARK, Anseong-si, Gyeonggi-do (KR); Junsung LEE, Anseong-si (KR)

(21) Appl. No.: 18/661,736

(22) Filed: May 13, 2024

(30) Foreign Application Priority Data
Jun. 7, 2023 (KR) 10-2023-0073164

(51) Int. Cl. H01L 21/683; B32B 3/26; B32B 18/00; C04B 37/00; H01L 21/687

(52) U.S. Cl. CPC H01L 21/6833; B32B 3/266; B32B 18/00; C04B 37/001; H01L 21/68785; C04B 2237/62; C04B 2237/64

(57) ABSTRACT

The present invention relates to a ceramic susceptor. A method of manufacturing the ceramic susceptor of the present disclosure May include steps of: manufacturing a plurality of ceramic sheets each including a via hole and a conductor filling the via hole; stacking the plurality of ceramic sheets; and sintering the stack body obtained by the stacking. In the stacking step, the via hole in at least one ceramic sheet among the plurality of ceramic sheets may be disposed not to overlap the via hole in another ceramic sheet adjacent thereto.

### CROSS-REFERENCE TO RELATED APPLICATION(S)

This application is based on and claims priority under 35 U.S.C. 119 to Korean Patent Application No. 10-2023-0073164, filed on Jun. 7, 2023, in the Korean Intellectual Property Office, the disclosure of which is herein incorporated by reference in its entirety.

### BACKGROUND OF THE INVENTION

### 1. Field of the Invention

The present disclosure relates to a ceramic susceptor and, in particular, to a multi-layer wiring structure of a ceramic insulating plate that supports a substrate.

### 2. Description of the Prior Art

In general, a semiconductor device or a display device is manufactured by sequentially laminating a plurality of thin film layers including a dielectric layer and a metal layer on a glass substrate, a flexible substrate, or a semiconductor wafer substrate and then patterning the thin film layers. These thin film layers are sequentially deposited on the substrate through a chemical vapor deposition (CVD) process or a physical vapor deposition (PVD) process. The CVD process includes a low-pressure chemical vapor deposition (LPCVD) process, a plasma-enhanced CVD (PECVD) process, a metal organic CVD (MOCVD) process, and the like.

In CVD and PVD apparatuses, ceramic susceptors are placed to support glass substrates, flexible substrates, semiconductor wafer substrates, or the like and to execute semiconductor processes. The ceramic susceptors may each include a chuck electrode installed in a CVD device or a PVD device to support a substrate, and a heating line configured to heat the substrate in a heat treatment process or the like. In addition, the ceramic susceptors may each include a radio frequency (RF) electrode instead of the heating wire or may further include a radio frequency (RF) electrode to be also used to form plasma in an etching process of thin film layers formed on a substrate.

FIGS. 1A, 1B, and 1C are views illustrating problems in conventional ceramic susceptors. FIGS. 1A and 1B are cross-sectional views of multilayer wiring structures of ceramic insulating plates, and FIG. 1C is a view illustrating the vicinity of via holes viewed from above in the process of stacking a multilayer wiring structure of a ceramic insulating plate.

First, referring to FIGS. 1A and 1B, in a multilayer wiring structure of a conventional insulating plate for supporting a substrate on a conventional ceramic susceptor, upper and lower wires are connected, for example, through via holes in stacked ceramic sheets, but various problems are exposed since the via holes are designed to be arranged in parallel to each other on a vertical line. For example, as illustrated in FIG. 1A, there is a problem in that disconnection occurs even if the vertical alignment of the via holes is slightly distorted, and as illustrated in FIG. 1B, there is a problem in that, when the ceramic sheets with printed wires are stacked and then pressed in a pre-sintered stack body state, the shapes of the via holes are not maintained and are deformed, increasing the possibility of disconnection.

Referring to FIG. 1C, for example, an electrode rod (not illustrated) configured to supply power is coupled to the lower portion of the ceramic insulating plate, and when the stack body is pressed, there is a problem in that, in particular, via holes 51 and 52 provided in the groove area where the electrode rod is coupled cannot maintain their shapes and undergo severe shape deformation, causing surface bending around the via holes inside the stack structure of the ceramic sheets, which further increases the possibility of disconnection.

### SUMMARY OF THE INVENTION

Accordingly, the present disclosure was made to solve the above-mentioned problems, and is to provide a ceramic susceptor that is manufactured such that, when pressed in a pre-sintered stack body state, shape deformation such as collapse is minimized in via holes in ceramic insulating plates having a multi-layer wiring structure, so that a deformed cross-sectional area is minimized, and a method of manufacturing the ceramic susceptor.

In addition, the present disclosure is to provide a ceramic susceptor in which via holes are not disposed in a groove area where an electrode rod configured to supply power is coupled under the ceramic insulating plates, but are disposed outside the groove, so that surface bending or the like does not occur and shape deformation is minimized in the vicinity of the via holes inside the stack structure of ceramic sheets, and a method manufacturing the ceramic susceptor.

First, to summarize the features of the present disclosure, a method of manufacturing the ceramic susceptor according to an aspect of the present disclosure may include the steps of: manufacturing a plurality of ceramic sheets each including a via hole and a conductor filling the via hole; stacking the plurality of ceramic sheets; and sintering the stack body obtained by the stacking. In the stacking step, the via hole in at least one ceramic sheet among the plurality of ceramic sheets may be disposed not to overlap the via hole in another ceramic sheet adjacent thereto.

Each of the ceramic sheets may have a wiring layer, which is electrically connected to the conductor in the via hole, on the surface or inside thereof.

The wiring layer may include an electrostatic chuck electrode, a high-frequency electrode, or a heating element.

The wiring layer may be formed in a plurality of some areas or an entire area of each ceramic sheet.

The step of manufacturing the plurality of ceramic sheets May include manufacturing a plurality of first ceramic sheets each having a plurality of first via holes at a first distance in a radial direction from a center, and the stacking step may include a step of stacking two or more of the plurality of first ceramic sheets in succession so that the via holes in the ceramic sheets are disposed at positions that do not overlap each other in the stacking direction.

The step of manufacturing the plurality of ceramic sheets may include manufacturing a plurality of first ceramic sheets each having a plurality of first via holes at a first distance in a radial direction from a center, and a plurality of second ceramic sheets each having a plurality of second via holes at a second distance in the radial direction from the center, and the stacking step may include a step of stacking one of the plurality of first ceramic sheets and one of the plurality of second ceramic sheets in succession so that the via holes in the ceramic sheets are disposed at positions that do not overlap each other in the stacking direction.

The step of manufacturing the plurality of ceramic sheets may include manufacturing a plurality of first ceramic sheets each having a plurality of first via holes at a first distance in a radial direction from a center, and a plurality of second ceramic sheets each having a plurality of second via holes at a second distance in the radial direction from the center, and the stacking step may include a step of stacking two or more of the plurality of first ceramic sheets in succession so that the via holes in the ceramic sheets are disposed at positions that do not overlap each other in the stacking direction, and a step of stacking one of the plurality of first ceramic sheets and one of the plurality of second ceramic sheets in succession so that the via holes in the ceramic sheets are disposed at positions that do not overlap each other in the stacking direction.

The stacking step may further include a step of stacking two or more of the plurality of second ceramic sheets in succession so that the via holes in the ceramic sheets are disposed at positions that do not overlap each other in the stacking direction.

In the stacking step, the via holes may not be disposed in a groove area, in which an electrode rod configured to supply power to the wiring layers of the plurality of ceramic sheets is disposed under the plurality of ceramic sheets, so that the via holes do not overlap each other in the stacking direction.

In addition, a ceramic susceptor manufactured by sintering a stack body obtained by stacking a plurality of ceramic sheets according to another aspect of the present disclosure may include a stack structure obtained by sintering the stack body in which the plurality of ceramic sheets each has a via hole and a conductor filled in the via hole, and the via hole in at least one ceramic sheet among the plurality of ceramic sheets may be disposed not to overlap the via hole in another ceramic sheet adjacent thereto.

Each of the plurality of ceramic sheets may include a wiring layer, which is electrically connected to the conductor in the via hole, on the surface or inside thereof.

The wiring layer may include an electrostatic chuck electrode, a high-frequency electrode, or a heating element.

The wiring layer may be formed in a plurality of some areas or an entire area of each ceramic sheet.

The plurality of ceramic sheets may include a plurality of first ceramic sheets each having a plurality of first via holes at a first distance in a radial direction from a center, and the ceramic susceptor may include two or more of the plurality of first ceramic sheets stacked in succession so that the via holes in the ceramic sheets are disposed at positions that do not overlap each other in a stacking direction.

The plurality of ceramic sheets may include a plurality of first ceramic sheets each having a plurality of first via holes at a first distance in a radial direction from a center, and a plurality of second ceramic sheets each having a plurality of second via holes at a second distance in the radial direction from the center, and the ceramic susceptor may include ceramic sheets in which one of the plurality of first ceramic sheets and one of the plurality of second ceramic sheets are stacked in succession so that the via holes in the ceramic sheets are disposed at positions that do not overlap each other in a stacking direction.

The plurality of ceramic sheets may include a plurality of first ceramic sheets each having a plurality of first via holes at a first distance in a radial direction from a center, and a plurality of second ceramic sheets each having a plurality of second via holes at a second distance in the radial direction from the center, and the ceramic susceptor may include ceramic sheets in which two or more of the plurality of first ceramic sheets are stacked in succession so that the via holes in the ceramic sheets are disposed at positions that do not overlap each other in a stacking direction, and ceramic sheets in which one of the plurality of first ceramic sheets and one of the plurality of second ceramic sheets are stacked in succession so that the via holes in the ceramic sheets are disposed at positions that do not overlap each other in the stacking direction.

The ceramic susceptor may further include two or more of the plurality of second ceramic sheets stacked in succession so that the via holes in the ceramic sheets are disposed at positions that do not overlap each other in a stacking direction.

The via holes may not be disposed in a groove area, in which an electrode rod configured to supply power to the wiring layers of the plurality of ceramic sheets is disposed under the plurality of ceramic sheets, so that the via holes do not overlap each other in the stacking direction.

According to a ceramic susceptor and a method of manufacturing the same according to the present disclosure, it is possible to provide a ceramic susceptor that is manufactured such that, when pressed in the pre-sintered stack body state, shape deformation such as collapse is minimized in the via holes in a ceramic insulating plate having a multi-layer wiring structure, so that the deformed cross-sectional area is minimized.

In addition, it is possible to provide a ceramic susceptor in which via holes are not disposed in a groove area where an electrode rod configured to supply power is coupled under the ceramic insulating plates, but are disposed outside the groove, so that surface bending or the like does not occur and shape deformation is minimized in the vicinity of the via holes inside the stack structure of ceramic sheets.

### BRIEF DESCRIPTION OF THE DRAWINGS

The accompanying drawings, which are included as a part of a detailed description to help the understanding of the present disclosure, provide embodiments of the present disclosure, and illustrate the technical spirit of the present disclosure together with the detailed description, in which:

FIGS. 1A, 1B, and 1C are views illustrating problems in conventional ceramic susceptors;

FIG. 2 is a flowchart illustrating a method of manufacturing a ceramic susceptor according to an embodiment of the present disclosure;

FIG. 3 is a flowchart illustrating the preparation, shape machining, and via hole machining of ceramic sheets in FIG. 2;

FIGS. 4A, 4B, 4C, and 4D are flowcharts illustrating a process of filling a conductor in via holes and printing wires in FIG. 2;

FIG. 5 is a schematic view of an exemplary stack body after the ceramic sheet stacking process in FIG. 2;

FIG. 6 is a view illustrating the positions of via holes disposed inside the exemplary stack body of FIG. 5 when viewed from above;

FIG. 7 is a view illustrating the positions of via holes appearing in a vertical cross section taken along line A-A in FIG. 6;

FIG. 8 is a photograph of a cross section of an insulating plate of a ceramic susceptor manufactured according to an embodiment of the present disclosure;

FIGS. 9A, 9B, 9C, and 9D are views illustrating embodiments in each of which a wiring pattern of a ceramic sheet of each layer of the present disclosure is formed in some areas; and

FIGS. 10A, 10B, 10C, and 10D are views illustrating embodiments in each of which a wiring pattern of a ceramic sheet of each layer of the present disclosure is formed in the entire area.

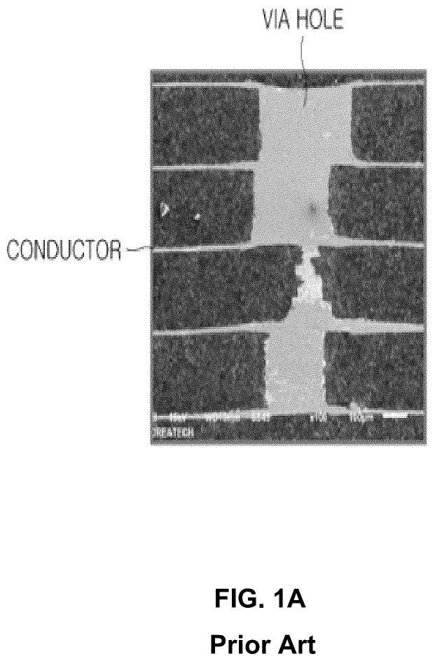

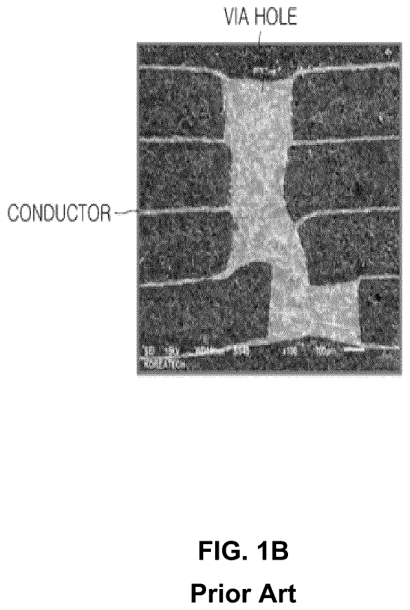

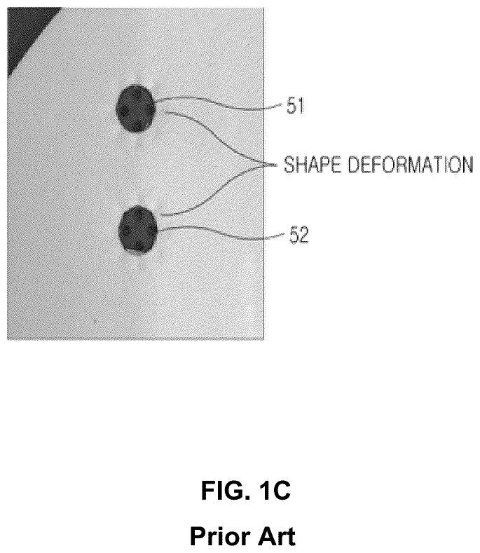

### DETAILED DESCRIPTION OF THE EXEMPLARY EMBODIMENTS

Hereinafter, the present disclosure will be described in detail with reference to the accompanying drawings. Herein, like components in each drawing are denoted by like reference numerals if possible. In addition, detailed descriptions of already known functions and/or configurations will be omitted. In the following description, components necessary for understanding operations according to various embodiments will be mainly described, and descriptions of elements that may obscure the gist of the description will be omitted. In addition, some elements in the drawings may be exaggerated, omitted, or schematically illustrated. The size of each component does not entirely reflect the actual size, and therefore, the descriptions provided herein are not limited by the relative sizes or spacings of the components drawn in each drawing.

In describing the embodiments of the present disclosure, when a detailed description of the known technology related to the present disclosure is determined to unnecessarily obscure the subject matter of the present disclosure, the detailed description will be omitted. In addition, terms to be described later are defined in consideration of functions in the present disclosure and may vary according to the intention, custom, or the like of a user or operator. Therefore, the definitions of the terms should be made based on the description throughout this specification. Terms used in the detailed description are only for describing the embodiments of the present disclosure, and should not be treated as limiting. Unless expressly used otherwise, singular forms of expressions include the meanings of plural forms of expressions. In this description, expressions such as “including” or “comprising” are intended to indicate any features, numbers, steps, operations, elements, or some or combinations thereof, and should not be construed to exclude the existence or possibility of one or more other features, numbers, steps, operations, elements, or some or combinations thereof, in addition to those described above.

In addition, terms such as “first” and “second” may be used to describe various components, but the components are not limited by the terms, and these terms are only used for the purpose of distinguishing one component from another.

First, in the present disclosure, the ceramic susceptor is a semiconductor apparatus used for processing processing-target substrates for various purposes such as a semiconductor wafer, a glass substrate, and a flexible substrate. The ceramic susceptor may include an electrostatic chuck electrode to be used as an electrostatic chuck to support a substrate to be processed, and may include a heating line (or a heating element) to heat a substrate to be processed to a predetermined temperature. Alternatively, the susceptor may further include a high-frequency electrode or may include a high-frequency electrode instead of the heating wire for process treatment, such as plasma enhanced chemical vapor deposition, for a processing-target substrate.

In addition, it should be noted that a ceramic sheet mentioned below refers to a ceramic green sheet, and that wires (or a wiring layer or wiring pattern) formed on the ceramic sheet include wires for the above-mentioned electrostatic chuck electrode, high-frequency electrode, or heating line (or heating element).

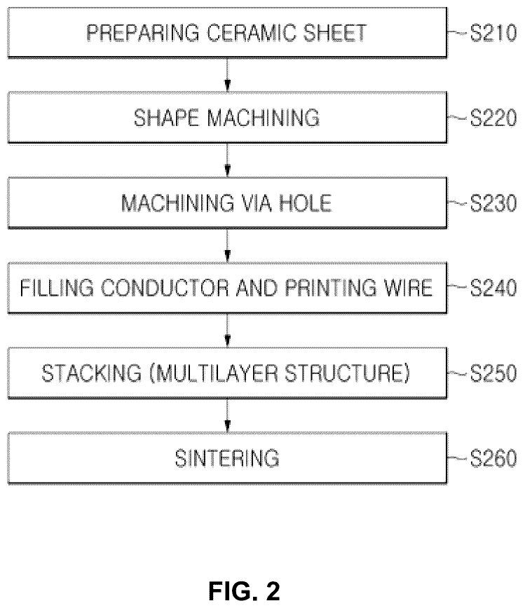

FIG. 2 is a flowchart illustrating a method of manufacturing a ceramic susceptor according to an embodiment of the present disclosure.

Referring to FIG. 2, a method of manufacturing a ceramic susceptor according to an embodiment of the present disclosure includes steps of manufacturing a plurality of ceramic sheets each including a via hole and a conductor filled in the via hole (S210 to S240), a step of forming a stack body by stacking the plurality of ceramic sheets (S250), and a step of sintering the stack body (S260).

The steps of manufacturing a plurality of ceramic sheets each including a via hole and a conductor filled in the via hole (S210 to S240) may include a step of preparing a ceramic sheet for manufacturing a ceramic susceptor (S210), a step of cutting and machining the prepared ceramic sheet to match the manufacturing shape of the susceptor (S220), a via hole machining step (S230), and a conductor filling and wire printing step (S240).

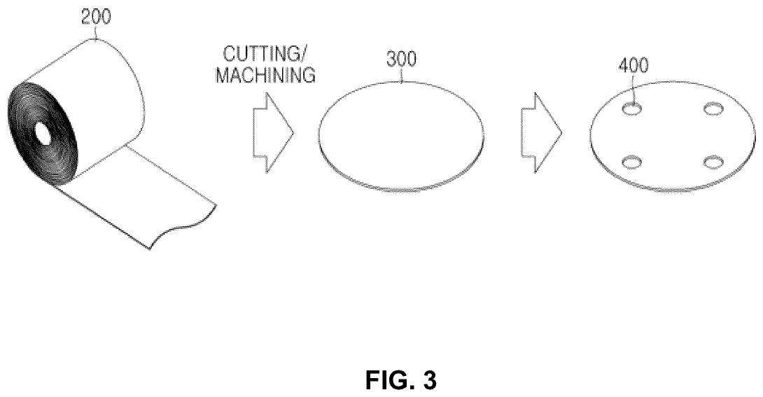

Hereinafter, a method for manufacturing a ceramic susceptor according to an embodiment of the present disclosure will be described in detail with reference to FIGS. 3 to 7.

FIG. 3 is a flowchart illustrating the ceramic sheet preparing process (S210), the shape machining process (S220), and the via hole machining process (S230) in FIG. 2.

Referring to FIG. 3, a ceramic sheet 200 manufactured on a carrier film in the form of a roll or the like may be prepared in the ceramic sheet preparing process (S210), the ceramic sheet 200 prepared in the shape processing process (S220) may be cut into a size required to match a manufacturing shape (e.g., a circular shape) of a ceramic susceptor of the present disclosure and machined into the manufacturing shape by a predetermined shape machining apparatus.

Next, via holes 400 are machined in a ceramic sheet 300 machined into a shape to match the manufacturing shape (e.g., a circular shape) of the ceramic susceptor of the present disclosure by a predetermined via hole processing apparatus (S230). As will be described later, when a plurality of ceramic sheets are stacked, the via holes 400 electrically connects, by a conductor filled therein, the wires of the corresponding ceramic sheet including the via holes 400 to the via holes or wires of a ceramic sheet therebeneath. The via holes in the ceramic sheets of respective layers serve to enable an electrostatic chuck electrode, a high-frequency electrode, or a heating wire (or heating element) to exert the functions thereof by being properly machined and filled with a conductor, and then electrically connecting the via holes or wires of the ceramic sheets of respective layers to each other.

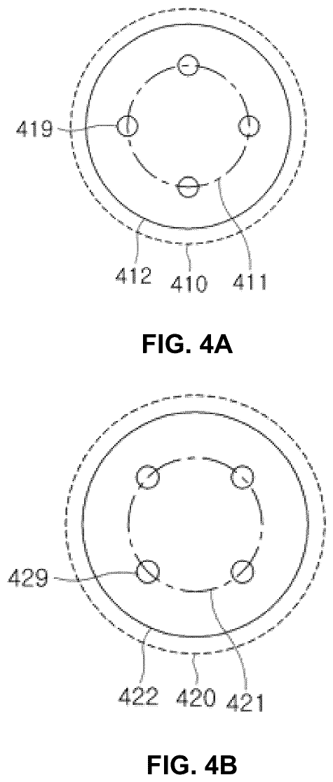

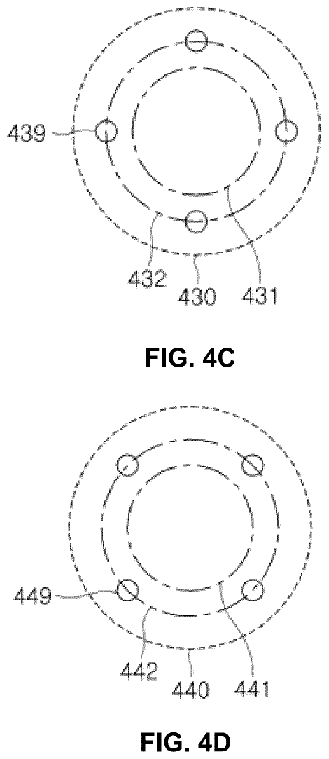

FIGS. 4A to 4D are flowcharts illustrating the process of filling via holes with a conductor and printing wires (S240) in FIG. 2.

Referring to FIGS. 4A to 4D, for example, after via holes 419, 429, 439, and 449 are machined in a plurality of ceramic sheets 410, 420, 430, and 440 in step S230, the via holes 419, 429, 439, and 449 are filled with a conductor, and various conductor pattern forming methods using conductive ink or paste of silver, copper, or the like may be used to form wires 411, 412/421, 422/431, 432/441, and 442 required for each ceramic sheet for each layer (S240). Each of the ceramic sheets may be prepared to include a wiring layer electrically connected to the conductors in the via holes 419, 429, 439, and 449, on the surface or inside, or both the surface and inside thereof.

When the plurality of ceramic sheets 410, 420, 430, and 440 are stacked, the via holes 419, 429, 439, and 449 electrically connect, by the conductor filled therein, the wires of the ceramic sheet including the via holes 419, 429, 439, and 449 to the via holes or wires of the ceramic sheet located therebeneath. The via holes 419, 429, 439, and 449 and the wires 411, 412/421, 422/431, 432/441, and 442 of the ceramic sheet of each layer may be formed in an appropriate pattern to electrically connect the wires of ceramic sheets of respective layers through the formation of the conductor. The pattern of the wires of the ceramic sheet of each layer may serve to enable an electrostatic chuck electrode, a high-frequency electrode, or a heating line (or heating element) to exert the functions thereof.

In addition, the via holes in each ceramic sheet may be or may not be connected to the electrostatic chuck electrode, high-frequency electrode, or heating line (or heating element). In a portion where a via hole in each ceramic sheet is not connected to the electrostatic chuck electrode, the high-frequency electrode, or the heating line (or heating element) and via holes of adjacent upper and lower sheets are electrically connected to each other, electrical connection may be made between via holes by being continuously overlapped on a straight line in the stacking direction of the ceramic sheets. In particular, as in the present disclosure, a conductor pattern extending from a via hole of the lower ceramic sheet to the periphery of the same may be electrically connected to a via hole in the upper ceramic sheet so that the via holes may not be overlapped on the straight line in the stacking direction. In the description of the present disclosure, “overlapping of via holes” means that, when via holes are projected in a normal direction on the surfaces of one ceramic sheet and another ceramic sheet, which are stacked to be adjacent to each other, the images of the projected via holes do not overlap each other.

As the various conductor pattern forming methods, for example, ink jet, gravure, gravure-offset, screen printing, and the like may be used. In some cases, photo lithography, electro plating, shadow mask and evaporator deposition, shadow mask and sputter deposition, machining by a computerized numerically controlled (CNC) machining tool, laser beam machining, electric discharge machining, and the like may also be used.

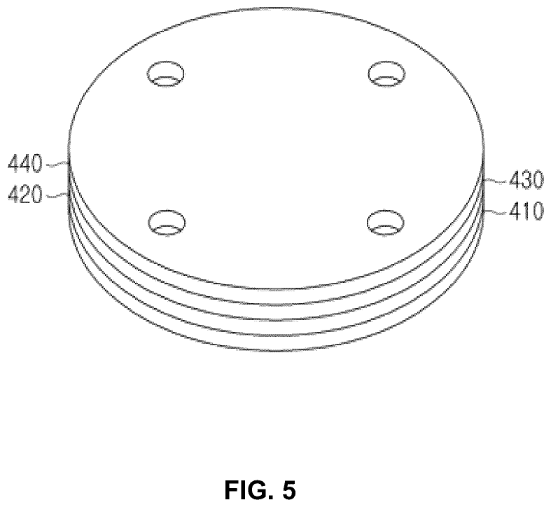

After the conductor filling and wire printing step (S240) is performed as described above, a stack body is formed by stacking the plurality of ceramic sheets 410, 420, 430, and 440 (S250) (see FIG. 5). At this time, pressure may be applied to the stack body.

Subsequently, the stack body (see FIG. 5) may be sintered through a predetermined sintering apparatus (S260). For example, in order to manufacture a ceramic susceptor of the present disclosure, the stack body may be sintered at a temperature of about 1600 to 1950° C. in the sintering process (S260).

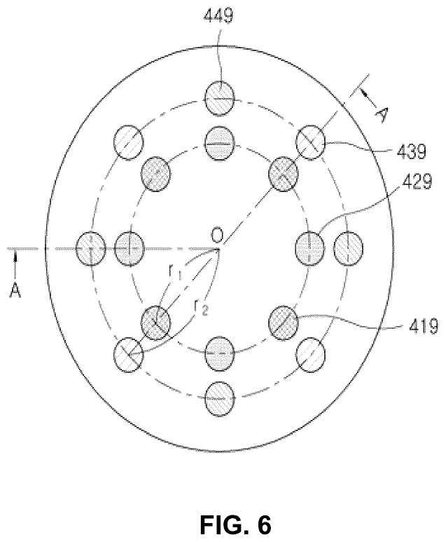

FIG. 6 is a view illustrating the positions of via holes disposed inside the exemplary stack body of FIG. 5 when viewed from above.

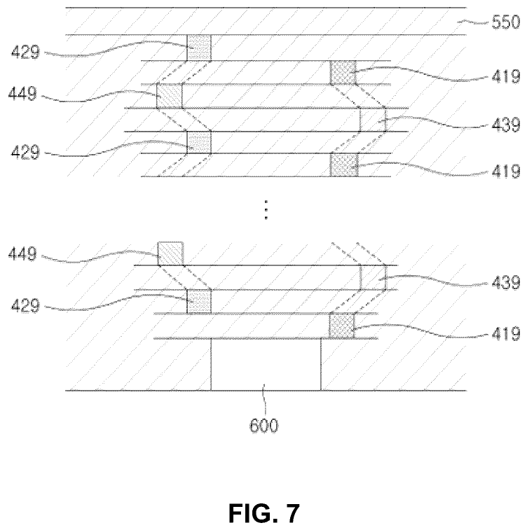

FIG. 7 is a view illustrating the positions of via holes appearing in a vertical cross section taken along line A-A in FIG. 6.

Referring to FIGS. 6 and 7, in the present disclosure, in the step of forming the stack body by stacking the plurality of ceramic sheets 410, 420, 430, and 440 (S250), the plurality of ceramic sheets 410, 420, 430, and 440 are stacked so that the via holes 419, 429, 439, and 449 in the plurality of ceramic sheets 410, 420, 430, and 440 are not continuous on a straight line in the stacking direction, i.e., do not overlap each other, and the vias holes or wires of the plurality of ceramic sheets 410, 420, 430, and 440 may be electrically connected to each other via the holes 419, 429, 439, and 449. An insulating material such as dielectric or ceramic may be added to the portion 550 above the plurality of ceramic sheets 410, 420, 430, and 440.

The number of layers of the plurality of ceramic sheets may be two or more, forming a multi-layer wiring structure. For example, the plurality of ceramic sheets 410, 420, 430, and 440 may be repeatedly stacked as illustrated in FIG. 7 to have various thicknesses depending on the purpose of a ceramic susceptor to be manufactured. However, in the present disclosure, by stacking all or some of the ceramic sheets so that the via holes 419, 429, 439, and 449 of the ceramic insulating plate having a multilayer wiring structure are not continuous and thus do not overlap each other on a straight line in the stacking direction, it is possible to provide a ceramic susceptor manufactured so that shape deformation such as collapse is minimized when pressed in the pre-sintered stack body state and thus the deformed cross-sectional area is minimized. That is, a via hole in at least one ceramic sheet among the plurality of ceramic sheets is preferably disposed not to overlap a via hole in another ceramic sheet adjacent thereto.

In the present disclosure, the stack body may be variously implemented in order to form an insulating plate of such a ceramic susceptor. Various embodiments below will be described with reference to FIGS. 4A to 4D, FIG. 5, and FIG. 6.

In the following embodiments, FIG. 4A illustrates a plurality of first ceramic sheets 410 having a plurality of first via holes 419 at a first distance r1 in the radial direction from the center O. FIG. 4B illustrates a plurality of first ceramic sheets 420 having a plurality of first via holes 429 at the first distance r1 in the radial direction from the center O in which the via holes 429 are arranged at an arrangement angle (e.g., a relative arrangement angle of 45 degrees) different from that in FIG. 4A. As illustrated, the first ceramic sheets 410 and 420 are sheets equally having a plurality of first via holes 419/429 at the first distance r1 in the radial direction from the center O, and only the relative arrangement angles of the via holes 419 and 429 are different.

FIG. 4C illustrates a plurality of second ceramic sheets 430 having a plurality of second via holes 439 at a second distance r2 in the radial direction from the center O. FIG. 4D illustrates a plurality of second ceramic sheets 440 having the plurality of second via holes 449 at the second distance r2 in the radial direction from the center O in which the via holes 449 are arranged at an arrangement angle (e.g., a relative arrangement angle of 45 degrees) different from that in FIG. 4C. As illustrated, the second ceramic sheets 430 and 440 are sheets equally having the plurality of second via holes 439/449 at the second distance r2 in the radial direction from the center O, and only the relative arrangement angles of the via holes 429 and 439 are different.

### Embodiment 1

First, in the step of preparing a ceramic sheet (S210), as illustrated in FIG. 4A (or FIG. 4B) and FIG. 6, a plurality of first ceramic sheets 410, each of which has a plurality of first via holes 419 at a first distance r1 in the radial direction from the center O, may be manufactured.

In step S250, among the plurality of first ceramic sheets 410, each of which has the plurality of first via holes 419 at the first distance r1, two or more first ceramic sheets 410 may be stacked in succession so that the via holes 419 in the corresponding ceramic sheets 410 are disposed at positions that are not continuous on a straight line in the stacking direction.

Depending on the purpose, the first distance r1 may be set in various ways, and in order to ensure that the via holes 419 of the ceramic sheets are disposed in positions that are not continuous on a straight line in the stacking direction, when four via holes 419 are formed in each ceramic sheet, for example, as illustrated in FIG. 4A, the arrangement angle between the via holes 419 in the ceramic sheet of each layer may be 45 degrees as illustrated in FIG. 6.

FIG. 6 exemplifies the case where the arrangement angle between the via holes 419 in the ceramic sheet of each layer is 45 degrees, but the present disclosure is not limited thereto. As long as the via holes 419 in the ceramic sheets are not continuous and thus do not overlap each other on a straight line in the stacking direction, the arrangement angle may be variously set to, for example, 10 degrees, 20 degrees, 30 degrees, 40 degrees, 45 degrees, 50 degrees, 60 degrees, 70 degrees, 80 degrees, or 90 degrees, considering the diameters of the via holes 419 and the number of via holes 419 for each ceramic sheet.

For example, in FIG. 6, except for the ceramic sheets 430 and 440 having the plurality of second via holes 439 and 449 at the second distance r2, in the above example, it is also possible to stack a plurality of first ceramic sheets 410 having a plurality of first via holes 419 at the first distance r1 in the manner of: stacking two ceramic sheets 410 such that the arrangement angle between the via holes 419 in the ceramic sheet of each layer is 45 degrees; and repeating this stacking (repeating the stacking of the sheets 410) such that the stack structure in which the via holes 410 in two ceramic sheets 410 are staggered as described above is repeated.

### Embodiment 2

In the ceramic sheet preparing step (S210), as illustrated in FIGS. 4B and 6, it is possible to manufacture a plurality of first ceramic sheets each having a plurality of first via holes 429 at the first distance r1 in the radial direction from the center O, and in as illustrated in FIGS. 4C and 6, it is possible to addition, manufacture a plurality of second ceramic sheets 430 having a plurality of second via holes 439 at a second distance r2 in the radial direction from the center O.

Accordingly, in the stack body stacking step (S250), it is possible to stack one of the plurality of first ceramic sheets 420 and one of the plurality of second ceramic sheets 430 in succession so that the via holes 429 and 439 in the corresponding ceramic sheets 420 and 430 are disposed at positions which are not continuous on a straight line in the stacking direction, as illustrated in FIG. 7. That is, since the via holes of ceramic sheets stacked in succession are located at different pitch circle diameters (PCDs), the via holes are naturally disposed at positions which are not continuous and thus do not overlap each other on a straight line in the stacking direction. In this case, it is possible to one of the plurality of first ceramic sheets 420 and one of the plurality of second ceramic sheets 430 in succession and to repeat this stacking (repeating the stacking of the sheets 420 and 430) such that the stack structure in which the via holes 429 and 439 in the first ceramic sheets 420 and the second ceramic sheets 430 do not overlap is repeated.

Depending on the purpose, the first distance r1 and the second distance r2 may be set variously, and since the via holes 429 and 439 in the ceramic sheets 420 and 430 have different distances from the centers of the ceramic sheets in the radial direction. Therefore, the via holes can be disposed at positions that are not continuous and thus do not overlap each other on a straight line in the stacking direction. However, in this case as well, for example, as illustrated in FIGS. 6 and 7, when four via holes 429 and 439 are formed in each ceramic sheet, the arrangement angle between the via holes 419 in the ceramic sheet of each layer may be 45 degrees.

FIG. 6 exemplifies the case where the arrangement angle between the via holes 429 and 439 in the ceramic sheets of each layer is 45 degrees, but the present disclosure is not limited thereto. As long as the via holes 429 and 439 in the ceramic sheets are not continuous and thus do not overlap each other on a straight line in the stacking direction, the arrangement angle may be variously set to, for example, 10 degrees, 20 degrees, 30 degrees, 40 degrees, 45 degrees, 50 degrees, 60 degrees, 70 degrees, 80 degrees, or 90 degrees, considering the diameters of the via holes 429 and 439 and the number of via holes 429 and 439 for each ceramic sheet.

### Embodiment 3

Furthermore, in Embodiment 2, it has been described that it is possible to one of the plurality of first ceramic sheets 420 and one of the plurality of second ceramic sheets 430 in succession and to repeat this stacking (repeating the stacking of the sheets 420 and 430) such that the stack structure in which the via holes 429 and 439 in the first ceramic sheets 420 and the second ceramic sheets 430 are not continuous is repeated, but the present disclosure is not limited thereto. As illustrated in FIGS. 6 and 7, by repeating a stack structure in which the via holes 419, 429 in two sheets 410 and 420 among the plurality of first ceramic sheets are not continuous, and a stack structure in which the via holes 439 and 449 in two sheets 430 and 440 among the plurality of second ceramic sheets are not continuous (repeating the first ceramic sheets 410 and 420 and the second ceramic sheets 430 and 440), it is possible to stack the ceramic sheets 410, 420, 430, and 440 such that the via holes 419, 429, 439, and 449 therein are disposed at positions that are not continuous and thus do not overlap each other on a straight line in the stacking direction.

### Embodiment 4

Furthermore, in Embodiment 3, instead of the stack structure in which the via holes 419 and 429 in two sheets 410 and 420 among the plurality of first ceramic sheets are not continuous, it is possible to stack a larger number of ceramic sheets among the plurality of first ceramic sheets such that corresponding via holes are disposed at positions that are not continuous and thus do not overlap each other on a straight line in the stacking direction.

That is, two or more first ceramic sheets can be stacked in succession, but the via holes in the ceramic sheets can be disposed at positions that are not continuous and thus do not overlap each other on a straight line in the stacking direction. At this time, as described in Example 1, it is possible to stack two ceramic sheets such that the arrangement angle between the via holes in the ceramic sheet of each layer is 45 degrees, and to repeat this stacking. Alternatively, as long as the via holes of the ceramic sheets are not continuous and thus do not overlap each other on a straight line in the stacking direction, the arrangement angle between the via holes in the ceramic sheet of each layer may be set various to, for example, 10 degrees, 20 degrees, 30 degrees, 40 degrees, 45 degrees, 50 degrees, 60 degrees, 70 degrees, 80 degrees, or 90 degrees, considering the diameters of the via holes and the number of via holes for each ceramic sheet.

### Embodiment 5

Furthermore, in Embodiment 3, instead of the stack structure in which the via holes 439 and 449 in two sheets 430 and 440 of the plurality of second ceramic sheets are not continuous, it is possible to stack a larger number of ceramic sheets among the plurality of second ceramic sheets such that corresponding via holes are disposed at positions that are not continuous and thus do not overlap each other on a straight line in the stacking direction.

That is, two or more second ceramic sheets can be stacked in succession, but the via holes in the ceramic sheets can be disposed at positions that are not continuous and thus do not overlap each other on a straight line in the stacking direction. At this time, as described in Example 1, here, it is also possible to stack two ceramic sheets such that the arrangement angle between the via holes in the ceramic sheet of each layer is 45 degrees, and to repeat this stacking. Alternatively, as long as the via holes of the ceramic sheets are not continuous and thus do not overlap each other on a straight line in the stacking direction, the arrangement angle between the via holes in the ceramic sheet of each layer may be set various to, for example, 10 degrees, 20 degrees, 30 degrees, 40 degrees, 45 degrees, 50 degrees, 60 degrees, 70 degrees, 80 degrees, or 90 degrees, considering the diameters of the via holes and the number of via holes for each ceramic sheet.

### Embodiment 6

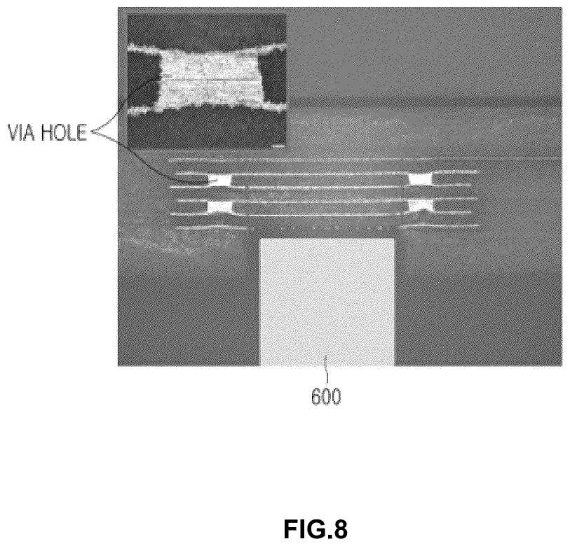

In addition, in the stack body forming step (S250), as illustrated in FIG. 7, in a groove area 600 in which an electrode rod configured to supply power to the wiring layers of a plurality of ceramic sheets 410, 420, 430, and 440 is disposed under the plurality of ceramic sheets 410, 420, 430, and 440, preferably, the via holes 419, 429, 439, and 449 are not provided in the stacking direction. Through via holes 419, 429, 439, and 449 and wires 411, 412/421, 422/431, 432/441, and 442 in each of the ceramic sheets 410, 420, 430, and 440, power can be supplied to all of the electrodes or conductors within the insulating plate. FIG. 8 is a photograph of a cross section of an insulating plate of a ceramic susceptor manufactured according to an embodiment of the present disclosure;

Referring to FIG. 8, it is possible to manufacture the insulating plate structure of the ceramic susceptor according to Embodiment 1 above such that two or more of the plurality of first ceramic sheets 410 are stacked in succession such that the via holes 419 of the ceramic sheets 410 are disposed at positions that are not continuous and thus do not overlap each other on a straight line in the stacking direction, and that the via holes are not disposed in a groove area 600 where an electrode rod configured to supply power is coupled under the ceramic insulating plates, but are disposed outside the groove, so that surface bending or the like does not occur and shape deformation is minimized in the vicinity of the via holes inside the stack structure of ceramic sheets.

### Embodiments of Wiring Pattern

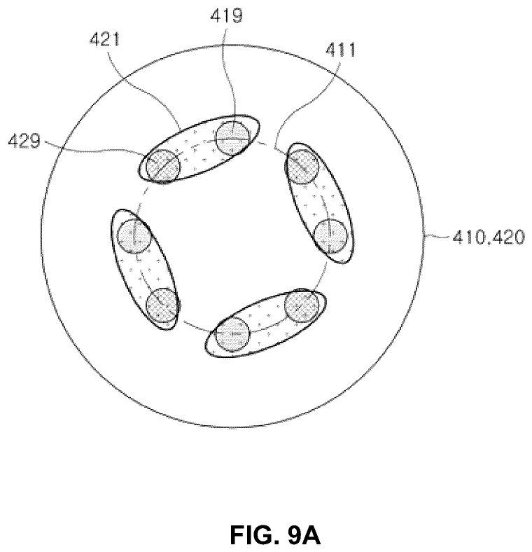

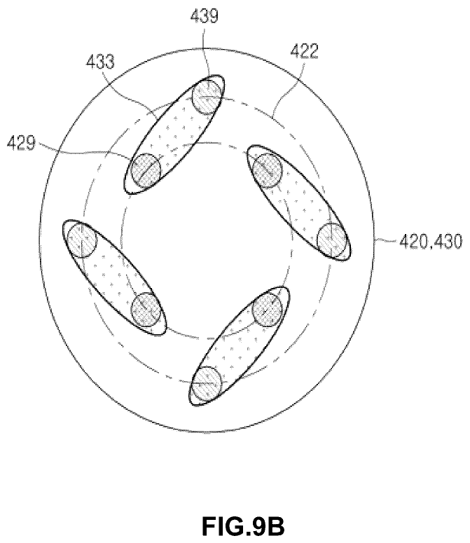

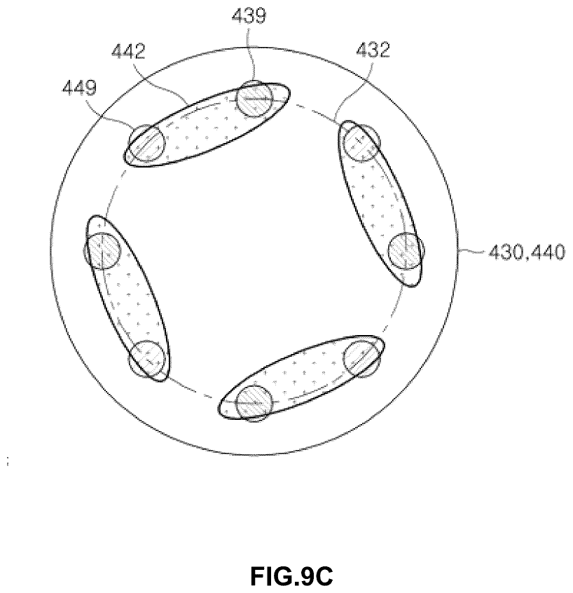

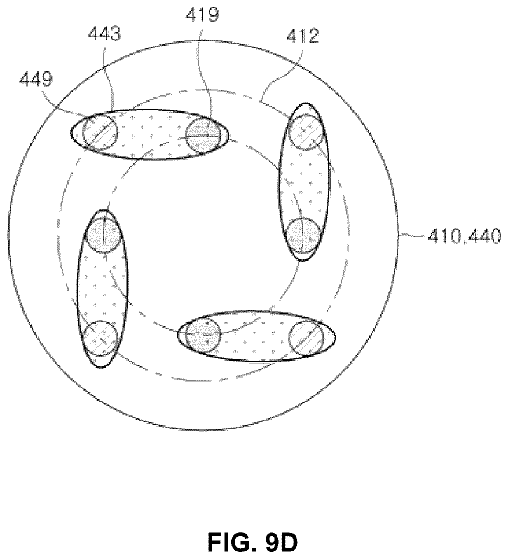

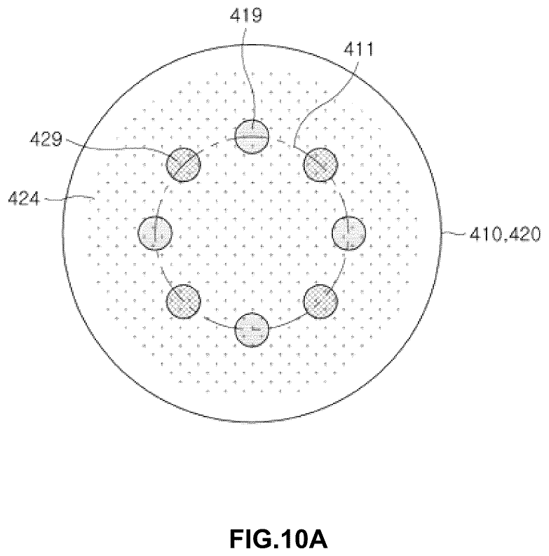

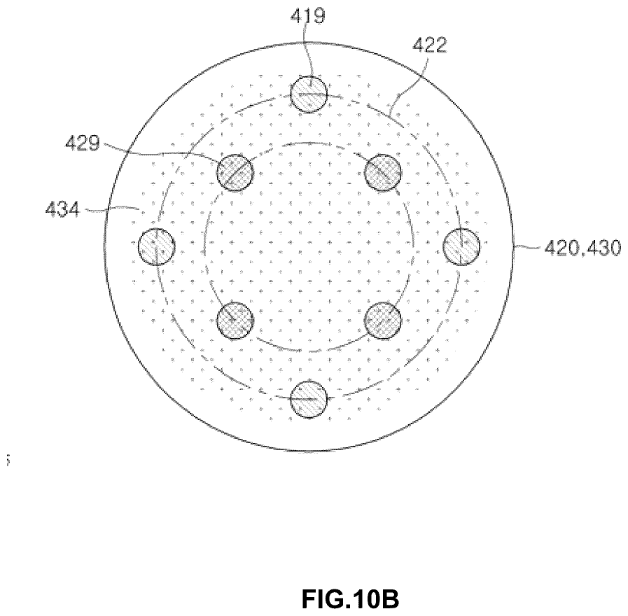

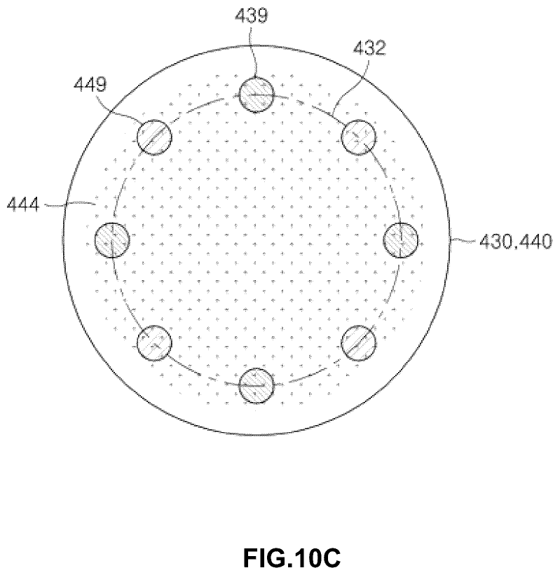

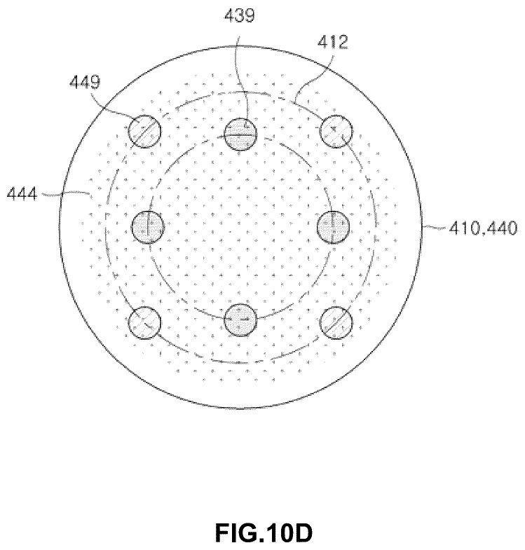

The embodiments for the wires 411, 412/421, 422/431, 432/441, and 442 in a stack body of a plurality of ceramic sheets 410, 420, 430, and 440 in the above-described embodiments will be described with reference to FIGS. 9A to 9D and FIGS. 10A to 10D.

FIGS. 9A to 9D are views illustrating embodiments in each of which a wiring pattern of a ceramic sheet of each layer of the present disclosure is formed in some areas; and

FIGS. 10A to 10D are views illustrating embodiments in each of which a wiring pattern of a ceramic sheet of each layer of the present disclosure is formed in the entire area.

The wires of the ceramic sheet of each layer of the present disclosure can be formed in some areas of some ceramic sheet and the entire areas of other sheets by combining FIGS. 9A to 9D and FIGS. 10A to 10D. Here, as illustrated in FIGS. 9A to 9D, the wires 421, 433, 442, and 443 in some areas are wires formed in each of some areas of predetermined divided portions of a ceramic sheet rather than the entire surface (or inside) of the ceramic sheet. In addition, as illustrated in FIGS. 10A to 10D, the wires 424, 434, and 444 in the entire area are wires extending to be connected without any divided portions across the entire surface (or inside) of a ceramic sheet, but there may be some empty wiring patterns at positions where gas holes are disposed.

For example, referring to FIG. 9A, in a stack body of a lower ceramic sheet 410 and an upper ceramic sheet 420 in which via hole arrangement angles are different, the wires 411 of the lower ceramic sheet 410 and the wires 421 in some areas of the upper ceramic sheet 420 may be electrically connected to each other via the via holes 429 in the upper ceramic sheet 420. The via holes 419 in the lower ceramic sheet 410 are electrically connected to the wires thereunder. In addition, referring to FIG. 10A, in a stack body of a lower ceramic sheet 410 and an upper ceramic sheet 420 in which via hole arrangement angles are different, the wires 411 of the lower ceramic sheet 410 and the wires 424 in the entire area of the upper ceramic sheet 420 may be electrically connected to each other via the via holes 429 in the upper ceramic sheet 420.

In addition, referring to FIG. 9B, in a stack body of a lower ceramic sheet 420 and an upper ceramic sheet 430 in which the distances of the via holes from the center are different, the wires 422 of the lower ceramic sheet 420 and the wires 433 in some areas of the upper ceramic sheet 430 may be electrically connected to each other via the via holes 439 in the upper ceramic sheet 430. The via holes 429 in the lower ceramic sheet 420 are electrically connected to the wires thereunder. In addition, referring to FIG. 10B, in a stack body of a lower ceramic sheet 420 and an upper ceramic sheet 430 in which the distances of the via holes from the center are different, the wires 422 of the lower ceramic sheet 420 and the wires 434 in the entire areas of the upper ceramic sheet 430 may be electrically connected to each other via the via holes 439 in the upper ceramic sheet 430.

In addition, referring to FIG. 9C, in a stack body of a lower ceramic sheet 430 and an upper ceramic sheet 440 in which via hole arrangement angles are different, the wires 432 of the lower ceramic sheet 430 and the wires 442 in some areas of the upper ceramic sheet 440 may be electrically connected to each other via the via holes 449 in the upper ceramic sheet 440. The via holes 439 in the lower ceramic sheet 430 are electrically connected to the wires thereunder. In addition, referring to FIG. 10C, in a stack body of a lower ceramic sheet 430 and an upper ceramic sheet 440 in which via hole arrangement angles are different, the wires 432 of the lower ceramic sheet 430 and the wires 444 in the entire area of the upper ceramic sheet 440 may be electrically connected to each other via the via holes 449 in the upper ceramic sheet 440.

In addition, referring to FIG. 9D, in a stack body of a lower ceramic sheet 410 and an upper ceramic sheet 430 in which the distances of the via holes from the center are different and the via holes are not adjacent to each other (see FIGS. 6 and 7), the wires 412 of the lower ceramic sheet 410 and the wires 443 in some areas of the upper ceramic sheet 430 may be electrically connected to each other via the via holes 449 in the upper ceramic sheet 430. Here, in order to connect a via hole 449 in the upper ceramic sheet 440 to a wire 412 of a lower ceramic sheet 410 which is not adjacent thereto, the via hole and the wire may be connected to each other via the via holes and wires of two ceramic sheets 420 and 430 between the lower ceramic sheet 410 and the upper ceramic sheet 440. Furthermore, in order to directly connect a via hole 449 in the upper ceramic sheet 440 to a wire 412 of the lower ceramic sheet 410 which is not adjacent thereto, it is possible to additionally machine a via hole 449 similar thereto. Likewise, referring to FIG. 10D, in a stack body of a lower ceramic sheet 410 and an upper ceramic sheet 430 in which the distances of the via holes from the center are different and the via holes are not adjacent to each other (see FIGS. 6 and 7), the wires 412 of the lower ceramic sheet 410 and the wires 444 in the entire area of the upper ceramic sheet 430 may be electrically connected to each other via the via holes 449 in the upper ceramic sheet 430.

As described above, the present disclosure provides a ceramic susceptor manufactured by sintering a stack body obtained by stacking a plurality of ceramic sheets 410, 420, 430, and 440. The ceramic susceptor includes a stack structure obtained by sintering a stack body obtained by stacking a plurality of ceramic sheets 410, 420, 430, and 440 in which a plurality of via holes 419, 429, 439, or 449 and wires 411, 412/421, 422/431, 432/441, 442 are formed. Here, the ceramic susceptor includes a plurality of via holes 419, 429, 439, or 449 which are disposed not to be continuous and thus do not overlap each other on a straight line in the stacking direction of the plurality of ceramic sheets 410, 420, 430, and 440. The plurality of via holes 419, 429, 439, or 449 are electrically connected to the wires 411, 412/421, 422/431, 432/441, and 442 of the plurality of ceramic sheets 410, 420, 430, and 440.

As described above, according to a ceramic susceptor and a method of manufacturing the same according to the present disclosure, it is possible to provide a ceramic susceptor that is manufactured such that, when pressed in the pre-sintered stack body state, shape deformation such as collapse is minimized in the via holes in a ceramic insulating plate having a multi-layer wiring structure, so that the deformed cross-sectional area is minimized. In addition, it is possible to provide a ceramic susceptor in which via holes are not disposed in a groove area 600 where an electrode rod configured to supply power is coupled under the ceramic insulating plates, but are disposed outside the groove, so that surface bending or the like does not occur and shape deformation is minimized in the vicinity of the via holes inside the stack structure of ceramic sheets.

As described above, the present disclosure has been described based on specific details, such as specific components, limited embodiments, and drawings, but these are only provided to help a more general understanding of the present disclosure, and the present disclosure is not limited to the above-described embodiments. A person ordinarily skilled in the art to which the present disclosure pertains may make various modifications and changes without departing from the essential characteristics of the present disclosure. Therefore, the spirit of the present disclosure should not be limited to the described embodiments, and not only the appended claims, but also all technical ideas that are equivalent to or equivalently modified to the claims should be interpreted as being included in the scope of the present disclosure.

What is claimed is:

1. A method of manufacturing a ceramic susceptor, the method comprising:
manufacturing a plurality of ceramic sheets each including a via hole and a conductor filling the via hole;
stacking the plurality of ceramic sheets; and
sintering a stack body obtained by the stacking,
wherein, in the stacking, the via hole in at least one ceramic sheet among the plurality of ceramic sheets is disposed not to overlap the via hole in another ceramic sheet adjacent thereto.

2. The method of claim 1, wherein each of the plurality of ceramic sheets comprises a wiring layer, which is electrically connected to a conductor in the via hole, on a surface thereof or therein.

3. The method of claim 2, wherein the wiring layer comprises an electrostatic chuck electrode, a high-frequency electrode, or a heating element.

4. The method of claim 2, wherein the wiring layer is formed in a plurality of some areas or an entire area of each ceramic sheet.

5. The method of claim 1, wherein the manufacturing of the plurality of ceramic sheets comprises manufacturing a plurality of first ceramic sheets each having a plurality of first via holes at a first distance in a radial direction from a center, and
wherein the stacking comprises stacking two or more of the plurality of first ceramic sheets in succession so that the via holes in the ceramic sheets are disposed at positions that do not overlap each other in a stacking direction.

6. The method of claim 1, wherein, the manufacturing of the plurality of ceramic sheets comprises manufacturing a plurality of first ceramic sheets each having a plurality of first via holes at a first distance in a radial direction from a center, and a plurality of second ceramic sheets each having a plurality of second via holes at a second distance in the radial direction from the center, and
wherein the stacking comprises stacking one of the plurality of first ceramic sheets and one of the plurality of second ceramic sheets in succession so that the via holes in the ceramic sheets are disposed at positions that do not overlap each other in a stacking direction.

7. The method of claim 1, wherein the manufacturing of the plurality of ceramic sheets may include manufacturing a plurality of first ceramic sheets each having a plurality of first via holes at a first distance in a radial direction from a center, and a plurality of second ceramic sheets each having a plurality of second via holes at a second distance in the radial direction from the center, and
wherein the stacking comprises:
stacking two or more of the plurality of first ceramic sheets in succession so that the via holes in the ceramic sheets are disposed at positions that do not overlap each other in a stacking direction; and
stacking one of the plurality of first ceramic sheets and one of the plurality of second ceramic sheets in succession so that the via holes of the ceramic sheets are disposed at positions that do not overlap each other in the stacking direction.

8. The method of claim 7, wherein the stacking further comprises:
stacking two or more of the plurality of second ceramic sheets in succession so that the via holes in the ceramic sheets are disposed at positions that do not overlap each other in a stacking direction.

9. The method of claim 1, wherein, in the stacking, the via holes are not disposed in a groove area, in which an electrode rod configured to supply power to the wiring layers of the plurality of ceramic sheets is disposed under the plurality of ceramic sheets, so that the via holes do not overlap each other in a stacking direction.

10. A ceramic susceptor manufactured by sintering a stack body obtained by stacking a plurality of ceramic sheets, the ceramic susceptor comprising:
a stack structure obtained by sintering the stack body in which the plurality of ceramic sheets each has a via hole and a conductor filled in the via hole,
wherein the via hole in at least one ceramic sheet among the plurality of ceramic sheets is disposed not to overlap the via hole in another ceramic sheet adjacent thereto.

11. The ceramic susceptor of claim 10, wherein each of the plurality of ceramic sheets comprises a wiring layer, which is electrically connected to a conductor in the via hole, on a surface thereof or therein.

12. The ceramic susceptor of claim 11, wherein the wiring layer comprises an electrostatic chuck electrode, a high-frequency electrode, or a heating element.

13. The ceramic susceptor of claim 11, wherein the wiring layer is formed in a plurality of some areas or an entire area of each ceramic sheet.

14. The ceramic susceptor of claim 10, wherein the plurality of ceramic sheets comprise a plurality of first ceramic sheets each having a plurality of first via holes at a first distance in a radial direction from a center, and
wherein the ceramic susceptor comprises two or more of the plurality of first ceramic sheets stacked in succession so that the via holes in the ceramic sheets are disposed at positions that do not overlap each other in a stacking direction.

15. The ceramic susceptor of claim 10, wherein the plurality of ceramic sheets comprise a plurality of first ceramic sheets each having a plurality of first via holes at a first distance in a radial direction from a center, and a plurality of second ceramic sheets each having a plurality of second via holes at a second distance in the radial direction from the center, and
wherein the ceramic susceptor comprises ceramic sheets in which one of the plurality of first ceramic sheets and one of the plurality of second ceramic sheets are stacked in succession so that the via holes in the ceramic sheets are disposed at positions that do not overlap each other in a stacking direction.

16. The ceramic susceptor of claim 10, wherein the plurality of ceramic sheets comprise:
a plurality of first ceramic sheets each having a plurality of first via holes at a first distance in a radial direction from a center; and
a plurality of second ceramic sheets each having a plurality of second via holes at a second distance in the radial direction from the center, and
wherein the ceramic susceptor comprises:
ceramic sheets in which two or more of the plurality of first ceramic sheets are stacked in succession so that the via holes in the ceramic sheets are disposed at positions that do not overlap each other in a stacking direction; and
ceramic sheets in which one of the plurality of first ceramic sheets and one of the plurality of second ceramic sheets in succession so that the via holes in the ceramic sheets are disposed at positions that do not overlap each other in the stacking direction.

17. The ceramic susceptor of claim 16, wherein the ceramic susceptor comprises ceramic sheets in which two or more of the plurality of second ceramic sheets are stacked in succession so that the via holes in the ceramic sheets are disposed at positions that do not overlap each other in a stacking direction.

18. The ceramic susceptor of claim 10, wherein the via holes are not disposed in a groove area, in which an electrode rod configured to supply power to the wiring layers of the plurality of ceramic sheets is disposed under the plurality of ceramic sheets, so that the via holes do not overlap each other in a stacking direction.
